(19) United States
(12) Patent Application Publication
(10) Pub. No.: US 2002/0041009 A1
(43) Pub. Date: Apr. 11, 2002

(54) Transmission line assembly chip and a manufacturing method thereof in a multi-chip module

(75) Inventors: Kazufumi Yamaguchi, Osaka (JP); Takeshi Shimamoto, Osaka (JP); Fumikazu Tateishii, Osaka (JP); Masahide Tsukamoto, Nara (JP); Takeo Ukai, Nara (JP)

Correspondence Address: GREENBLUM & BERNSTEIN, P.L.C., 1941 ROLAND CLARKE PLACE, RESTON, VA, 20191, US

(73) Assignee: MATSUSHITA ELECTRIC INDUSTRIAL CO., Ltd, Osaka (JP)

(21) Appl. No.: 09/897,133

(22) Filed: Jul. 3, 2001

(30) Foreign Application Priority Data
Jul. 5, 2000 (JP) 2000-203373

(51) Int. Cl. H01L 29/40

(52) U.S. Cl. 257/664

(57) ABSTRACT

In a transmission line assembly chip for connection between semiconductor chips, strap-like metallic films and dielectric films are alternately arranged in parallel in a transverse direction, so that an aspect ratio of each transmission line conductor is larger than 1. The assembly chip is formed by laminating metallic foils and dielectric films and cutting the same into a specified thickness to achieve favorable matching of characteristic impedances of the transmission lines.

The present disclosure relates to subject matter contained in priority Japanese Patent Application No. 2000-203373, filed on Jul. 5, 2000, the contents of which is herein expressly incorporated by reference in its entirety.

### BACKGROUND OF THE INTENTION

1. Field of the Invention

The present invention generally relates to a transmission line assembly chip and a manufacturing method thereof, and in particular to a transmission line assembly chip composed by alternately arranging metallic foils and dielectric films for rapid transmission of signals between semiconductor chips in a multi-chip module.

2. Description of the Prior Art

A high-speed processing as well as high integration in semiconductor chips has been achieved in accordance with progresses in device technology, process technology and circuitry technology. In terms of high speed processing, clock frequencies of CPUs and logic LSIs have already reached to a level in products as high as 1 GHz. On the other hand, an upper limit of clock frequencies for transmitting signals on a circuit board is still remaining at 400 MHz. This is due to a fact that, when compared to wirings within semiconductor chips, the transmission lines for transmitting signals between semiconductor chips on a circuit board exhibit large manufacturing variations in view of characteristic impedance and to a fact that cross-talks between signals are also large.

As a consequence, high-speed signal rates cause larger effects of reflection and cross-talk noise to be hindrance for high-speed processing. In other words, conventional transmission lines formed on a circuit board are of low wiring density, and line pitches or line widths and thickness of wirings are not uniform, and therefore high operating performances of the semiconductor chips can not be fully utilized.

Also, in conventional wiring connection between semiconductor chips on a circuit board, the wiring lines are provided in a radial manner from each of the semiconductor chips in order to prevent interference between adjacent lines. This makes it difficult to arrange the wiring lines in parallel with high wiring density.

In more detail, FIG. 11 shows an example of a conventional LSI module mounted on a circuit board. LSI is subject to fine processing with a high accuracy processing device, and a number of pads for connection is remarkably increased in accordance with a high integration and it becomes popular for LSI to have more than several hundreds of pads in number. Accordingly, the pitch of the pads formed on respective four sides of the LSI chip becomes approximately 50 μm. On the other hand, regarding the circuit board for supporting the LSI and for electrically connection thereof, it is difficult to maintain a high processing accuracy in view of manufacturing cost and size of the circuit board. Thus, the line pitch of the wiring pattern on the circuit board still remains at a level of about 200 μm.

By this reason, as shown in FIG. 11, each LSI is mounted on an interposer for expand the pad pitch for connection, and then the wiring lines are connected to the wiring pattern formed on the circuit board having a comparatively rough wiring pitch. In this method, however, the lengths of the wirings of the signal bus are different and uniformity of the characteristic impedance thereof can not be maintained.

Also, in a fine processing by such as etching or printing method, it is essentially necessary to reduce the thickness of the wiring as the width thereof is reduced. That is, it is impossible to make a wiring pattern having an aspect ratio being larger than 1.

While developments are being made in the field of circuit boards for achieving enlargement of aspect ratios of wirings and low dielectric constant (i.e., permittivity) of circuit boards in order to improve the signal transmitting speed, demands for rapid transmission of signals are not yet achieved.

A technique for enlarging aspect ratios of circuit boards is disclosed, for instance, in Japanese Patent Unexamined Publication No. 6-209151 (1994). This publication discloses a method for manufacturing a circuit board wherein molten resin is press-fit into a mold formed with convex portions in accordance with circuit pattern shapes to form a circuit board with circuit pattern portions formed to be as concave portions, and wherein a conductive paste is filled into these concave portions.

Another Japanese Patent Unexamined Publication No. 5-63373 (1993) discloses a method for manufacturing a large current circuit of large aspect ratio wherein an insulating sheet formed with slits at portions corresponding to a large current circuit is laminated on a circuit board, and a conductive paste is filled into the concave portions formed by the slits for curing.

While conductive lines are formed by embedding conductive paste into concave portions in all of the above publications, because conductive lines formed through conductive paste are aggregations of metallic particles, there arise a drawback in that resistance values are larger than those of metallic foils obtained by rolling, owing to pores formed between particles and contact resistance between particles.

It is further known to form conductive lines through filling by utilizing a plating method with which it is possible to form more minute conductive lines; however, it takes a lot of time for the forming. Such methods for forming circuit wirings by using molds or slits are disadvantaged in that the accuracy of circuitry patterns that are formed on circuit boards is limited depending on materials of the circuit boards, and that the filling density of conductive materials that are filled into narrow concave portions may be problematic. It is therefore evident that while such manufacturing methods are suitable for manufacturing circuit boards for power circuits coping with large current with a rough pattern density, they are not appropriate for manufacturing circuit boards including rapid transmission lines of large pattern density.

Accompanying improvements in degrees of integration of semiconductor chips in a circuit board of a multi-chip module, the number of required connecting electrodes (electrode pads) will also increase to thereby result in an increase in the number of wirings for transmitting signals between the semiconductor chips. It is therefore required that the wirings are formed with even higher density on the circuit boards. When increasing the wiring density, it will result in smaller line width and thickness of the wirings, which results in higher wiring resistances, and also in increased unevenness of line width and thickness of the wirings.

Such factors will cause increased manufacturing variations in view of characteristics impedances of transmission lines signal conductors between semiconductor chips, and cause larger reflection of signals and cross-talks between adjacent signals.

While there are known methods for improving the substantial wiring density through multi-layered wirings, drawbacks are presented in that it will be necessary for connection between layers and in that degradations in matching performances of characteristic impedances are observed. It was due to those factors that the upper limit for a clock frequency of circuit boards remained at the level of approximately 400 MHz even though signal transmission of a clock frequency of 1 GHz is possible on semiconductor chips.

### SUMMARY OF THE INVENTION

It is an object of the present invention to solve this problem and to provide a transmission line chip and manufacturing method thereof with reduction of variations in characteristic impedances between transmission lines in transmission line chips by keeping the uniformity of line widths, thicknesses and line pitches of the transmission lines.

In order to achieve the objects, a first aspect of the present invention provides a transmission line assembly chip which comprises an array of strap-like metallic films serving as transmission lines and dielectric films, wherein the metallic films and dielectric films are alternately arranged in parallel in a transverse direction thereof. In this arrangement, an aspect ratio of each transmission line of the metallic film is made larger than 1.

The transmission lines may be disposed an insulation supporting substrate, and further a conductive film may be formed on a rear surface of the insulation supporting substrate.

Moreover, end portions of the strap-like metallic films and the dielectric films may be projected longer by a specified length than the insulation supporting substrate, and terminal connection mechanisms may be provided near the both end portions of the strap-like metallic films. The terminal connection mechanisms may be of electrode pads or connection holes buried with electric conductive materials.

By this arrangement of the transmission line assembly chip, line width and thickness of the respective transmission lines are determined by an initial shape of the metallic films while the line pitch is determined by the thickness of the respective dielectric films, and it is easy to maintain of unity of the respective members since no pattern forming processes are necessary during the manufacturing processes. Thus, variations in the characteristic impedances of transmission lines are made small.

The aspect ratio of the respective transmission lines is larger than 1 while the wiring resistance thereof is small considering their line width, and it is thus possible to reduce transmission losses. By further setting the thickness of the metallic films and the dielectric films to several tens of μm, it is possible to easily form transmission lines with pitches of the lines being not more than 100 μm.

A second aspect of the present invention provides a multi-chip module which comprises: semiconductor chips electrically connected through a transmission line assembly chip, wherein the transmission line assembly chip has an array of strap-like metallic films serving as transmission lines and dielectric films, wherein the metallic films and dielectric films are alternately arranged in parallel in a transverse direction thereof.

The pitches of electrode pads of the semiconductor chips may be coincident with pitches of the array of the metallic films of the transmission line assembly chip. Moreover, a height of the insulation supporting substrate may be identical to a height of the semiconductor chips.

Thus, in the multi-chip module, the semiconductor chips are electrically connected with each other through the transmission line chip. The transmission line chip is particularly used as a bus line between semiconductor chips requiring rapid transmission. It is difficult to arrange the entire module substrate as a structure of the described transmission lines in view of manufacturing methods as well as costs thereof.

Therefore, by forming the transmission lines as chip-like structures and disposing them at locations of the module structure that particularly require rapid signal transmission, it is possible to exhibit rapid transmission performance besides simplification of manufacturing methods. In case array pitches of the transmission lines are made to be coincident with pitches of the electrode pads of the semiconductor chips, it is possible to achieve high accuracy of mounting processes.

In case a thickness of an insulation supporting substrate adhered to a lower surface of the transmission line chip is made to be coincident with a thickness of the semiconductor chips, and end portions of strap-like metallic foils and dielectric films are made to project by specified lengths, it will be easy to electrically connect the electrode pads of the semiconductor chips with the transmission lines and further to decrease stress applied on the connecting portions to thereby improve reliability of connection.

For forming the transmission line assembly chip, metallic films and dielectric films of desired thickness are alternately arranged in respective thickness directions to compose a sandwich structure made of the metallic films and the dielectric films, and by cutting a section of the structure into a desired thickness, a first transmission line assembly chip is obtained. By adhering a rear surface of the first transmission chip onto an insulation supporting substrate of a desired thickness, a second transmission line assembly chip having an insulating substrate is obtained.

### BRIEF DESCRIPTION OF THE DRAWINGS

These and other objects and features of the present invention will be readily understood from the following detailed description taken in conjunction with preferred embodiments thereof with reference to the accompanying drawings, in which like parts are designated by like reference numerals and in which:.

FIGS. 1A and 1B are views illustrating a transmission line chip according to a first embodiment of the present invention;

FIGS. 2A and 2B are views illustrating an arrangement of a transmission line chip interposed between semiconductor chips according to a first embodiment of the present invention;

FIGS. 3A and 3B are views illustrating a transmission line chip according to a second embodiment of the present invention;

FIGS. 4A and 4B are views illustrating a transmission line chip according to a third embodiment of the present invention;

FIGS. 5A and 5B are views illustrating a transmission line chip according to a fourth embodiment of the present invention;

FIGS. 6A and 6B are views illustrating a multi-chip module according to a fifth embodiment of the present invention;

FIG. 7 is a view showing processes for manufacturing a transmission line chip according to a sixth embodiment of the present invention;

FIG. 8 is a view showing processes for manufacturing a transmission line chip according to the sixth embodiment of the present invention;

FIG. 9 is a view showing processes for manufacturing a transmission line chip according to the sixth embodiment of the present invention;

FIG. 10 is a view showing processes for manufacturing a transmission line chip according to the sixth embodiment of the present invention; and

FIG. 11 is a model view showing a conventional example of LSI module mounted on a circuit board.

### DETAILED DESCRIPTION OF THE PREFERRED EMBODIMENT

Embodiments of the present invention will now be explained with reference to the drawings.

### EMBODIMENT 1

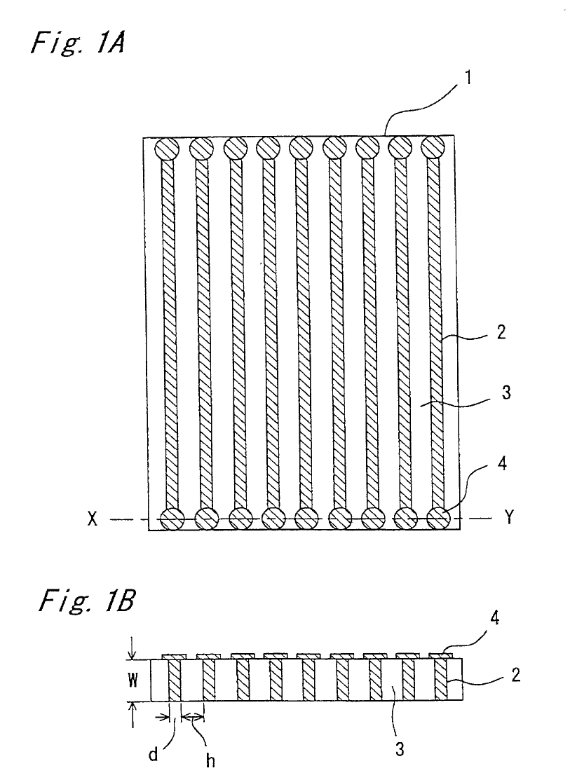

FIG. 1A illustrates a plan view of a transmission line assembly chip 1 according to the first embodiment of the present invention, and FIG. 1B shows a sectional view thereof when cut along a cutting surface X-Y. In the drawings, reference numeral 2 denotes strap-like metallic foils or films serving as transmission line conductors or wirings, reference numeral 3 denotes strap-like dielectric films or layers serving as insulating regions, and reference numeral 4 denotes electrode pads of the transmission lines 2. The transmission line assembly chip 1 has a construction in which a plurality of strap-like metallic films 2 and dielectric films 3 are alternately laminated in a transverse direction (i.e., X-Y direction in the drawing) in parallel so as to obtain a specified characteristics impedance. The electrode pads 4 are formed of e.g. projecting electrodes provided on both end portions of the metallic films 2 for connection with electrode pads formed on semiconductor chips and the like electronic elements. These electrode pads are formed by a method of, for example, printing, plating or ball bonding.

As it can be seen from FIG. 1B, according to the structure of the transmission line assembly chip 1, since the strap-like metallic films 2 and strap-like dielectric films 3 are alternately arranged in the transverse direction (i.e., X-Y direction) in parallel, it can be easily realized to set the aspect ratio to be larger than 1 by increasing the width W in height direction (i.e., in a direction perpendicular to the chip surface) of the strap-like metallic films 2 compared to the thickness d in the transverse direction (i.e., X-Y direction) thereof. For instance, by defining each strap-like metallic film 2 to be of a thickness d of 20 μm and a width W of 100 μm, the aspect ratio will be 5. By this arrangement, it is possible to solve a conventional problem by achieving an aspect ratio exceeding 1. That is, in the conventional case where transmission line conductors are formed into planar structures, it has been difficult to achieve this feature no matter which one of the plating, printing or etching methods is employed.

By setting the thickness d of the strap-like metallic film 2 and the thickness h of the dielectric film 3 to be respectively uniform, it is possible to form a transmission line chip assembly of high density together with uniform characteristic impedance. Thus, it will consequently be possible to reduce signal reflection and cross-talk and to achieve high-speed processing of signal rates. In the case where the thickness d of the strap-like metallic film 2 is set to 20 μm and the thickness h of the dielectric film 3 to 50 μm, a line pitch becomes 70 μm, and it is possible to form 14 transmission lines per a distance of 1 mm to thereby obtain an extremely high density of transmission lines.

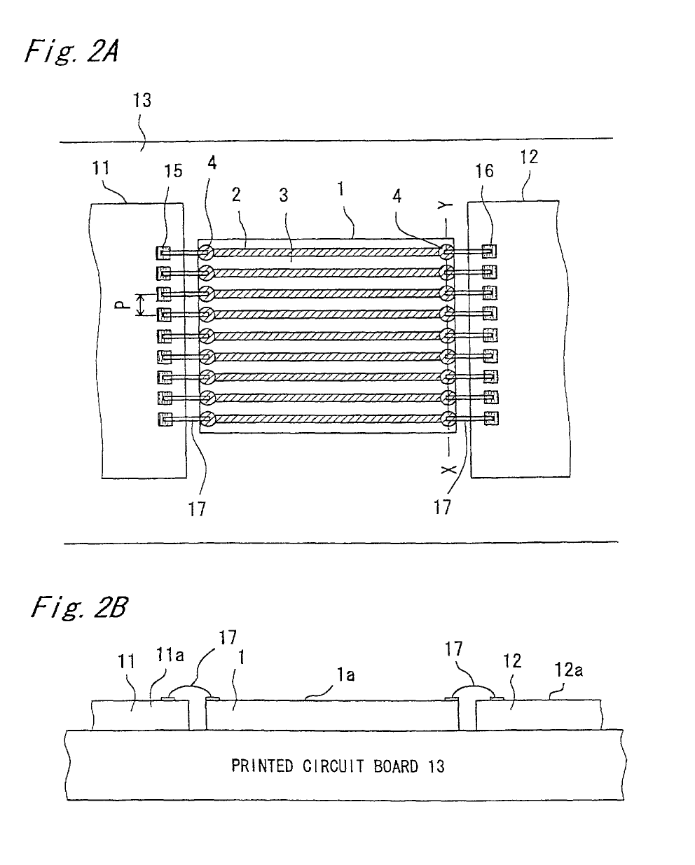

In FIG. 2A, the transmission line assembly chip 1 having the electrode pads 4 is mounted onto a printed circuit board 13 and is interposed between two semiconductor chips 11 and 12 which are die-bonded to the printed circuit board 13. The semiconductor chips 11 and 12 have I/O electrode pads 15 and 16, respectively, corresponding to the electrode pads 4. In this arrangement, the electrode pads 4 provided on the transmission line assembly chip 1 are respectively connected to the I/O electrode pads 15 and 16 provided on the semiconductor chips 11 and 12 by means of wire-bonding 17 to thereby achieve the high-speed transmission of signals between the two semiconductor chips.

In this arrangement, the pitch p of the electrode pads 4 on the transmission line assembly chip 1 is matched with the pitch of the I/O electrode pads 15 and 16 provided on semiconductor chips 11 and 12. Thus, the electrical connection by the wire-bonding 17 can be facilitated and transmission loss of signals can be reduced at the connecting portions.

As shown in FIG. 2B, the thickness in height of the transmission line assembly chip 1 is made coincident to the thickness in height of the semiconductor chips 11 and 12. Thus, the level in height of the upper surface la of the transmission line assembly chip 1 is made coincident with the level in height of the upper surfaces ha and 12a of the semiconductor chips 11 and 12. Therefore, the surfaces of the transmission line assembly chip 1 and semiconductor chips 11 and 12 are made uniform to thereby facilitate the electrical connection by the wire-bonding 17 between the electrode pads 4 and the I/O electrode pads 15 and 16.

In this arrangement, although the electrical connection between the electrode pads 4 and the I/O electrode pads 15 and 16 is made by the wire-bonding 17, it is not limited to this, and the connection can be also performed by, e.g., a TAB (tape automated bonding) method.

In the transmission line assembly chip 1 as shown in FIG. 1B, when the metallic film 2 has a thickness being d mm and width being W mm and the dielectric film 3 has a thickness being h mm and width being V mm (=W mm), a characteristic impedance of transmission signal conductors is given by [Equation 1] in the case where the metallic films 2 are alternately used as signal conductors and ground conductors.

$${Z}_{0} = \frac{h}{2 W} \sqrt{\frac{μ}{ϵ}} = \frac{h}{2 W} \cdot \frac{377}{\sqrt{ϵ}} \qquad \text{[Equation 1]}$$

When setting the respective values to satisfy d=0.02 mm, W=0.1 mm, and h=0.05 mm and a specific inductive capacity of the dielectric films 3 to satisfy ε=3.6, the characteristic impedance of the transmission line chip 1 will be approximately 50Ω. As apparent from Equation 1, by reducing the respective sizes while maintaining the ratio of h/W constant, it is possible to increase the wiring density of the transmission lines while maintaining the characteristic impedance constant.

Though not shown in the drawings, it is possible to further improve reliability by forming an insulating thin protection film on both or either one of the upper and lower surfaces of the transmission line assembly chip of the present invention. Moreover, it is noted here that, although the respective transmission lines of the transmission line assembly chip are formed as straight-linear shapes in FIG. 1A, these lines can be also arranged in a bent manner as in flexible wiring boards, if required, in the case of using metallic films For transmission conductors and resin for forming the dielectric films.

### EMBODIMENT 2

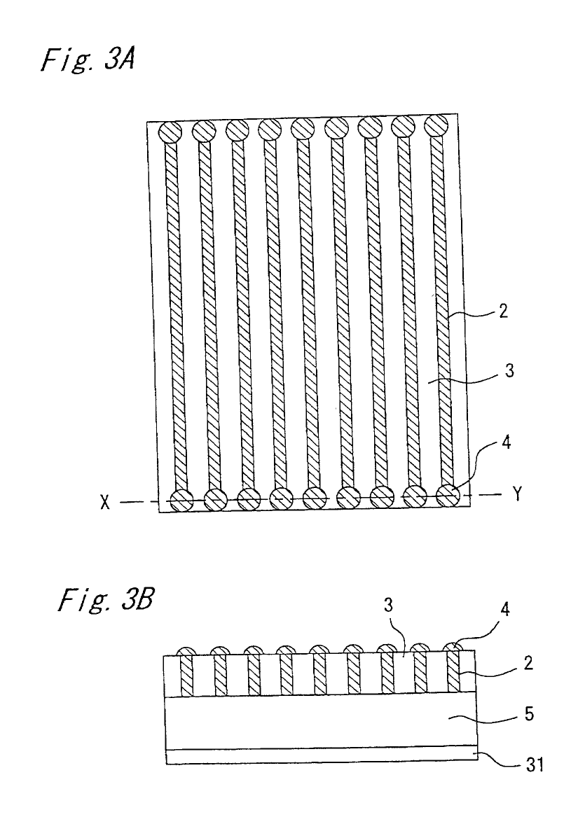

FIG. 3A illustrates a plan view of a transmission line assembly chip 1 according to the second embodiment of the present invention, and FIG. 3B shows a sectional view thereof when cut along cutting surface X-Y. The strap-like metallic films 2, strap-like dielectric films 3, and electrode pads 4 of the transmission lines are similar to those of the first embodiment and the explanation thereof is omitted here. The specific feature of the present embodiment 2 resides in the fact that an insulating supporting substrate 5 is further provided for supporting the transmission line assembly chip 1 composed of the strap-like metallic films 2, strap-like dielectric films 3, and electrode pads 4. The supporting substrate 5 made of an insulating material.

The assembly chip 1 is composed of a plurality of strap-like metallic films 2 and dielectric films 3 that are alternately arranged in the transverse direction (X-Y direction) so as to satisfy a specified characteristic impedance, and the assembly chip is adhered onto the supporting substrate 5. Since the strap-like metallic films 2 are formed in a manner embedded within the strap-like dielectric films 3 in height directions thereof, the aspect ratio can be easily increased, as described in the first embodiment. By providing the insulation supporting substrate 5, it is effective in enabling simple handling of the transmission line assembly chip 1 in mounting processes and further in decreasing electric connection between transmission lines 2 of the assembly chip 1 and wiring conductors of the circuit board 13.

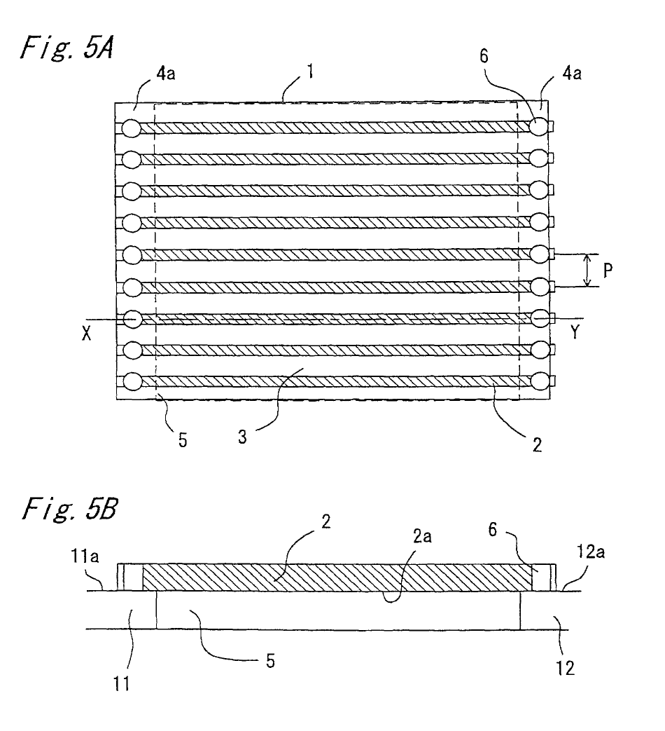

Moreover, as shown in FIG. 5B, it is also possible to form a conductive film 31 on a rear surface of the supporting substrate 5, and in the case where the metallic films 2 are alternately used as signal conductors and ground conductors, transmission signals may be shut-in by the adjoining transmission lines and the conductive film 31, thereby obtaining the effect of further reducing cross-talk between signal transmission lines. The same effect may be achieved when adhering the transmission line chip assembly 1 of the first embodiment onto a circuit board of which the outermost surface is a ground surface.

### EMBODIMENT 3

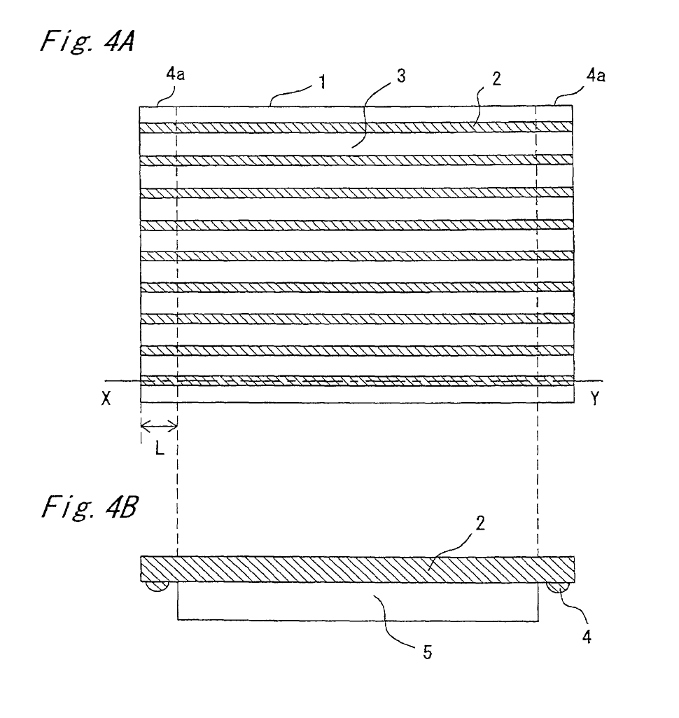

FIG. 4A illustrates a plan view of a transmission line assembly chip 1 according to -the third embodiment of the present invention, and FIG. 4B shows a sectional view thereof when cut along cutting surface X-Y. The strap-like metallic films 2, strap-like dielectric films 3, electrode pads 4 of the transmission lines, and supporting substrate 5 made of an insulating material are similar to those of the second embodiment, and the explanation thereof is omitted here.

The present embodiment differs from the second embodiment in that end portions of the metallic films 2 and the dielectric films 3 are projected out from the insulating supporting substrate 5 by specified lengths L to have a projecting portions 4a of the both side ends in the present embodiment. In this construction, electrode pads 4 such as metallic bumps of the projecting portions 4a are formed for connection on the lower surfaces of the respective metallic films 2.

When the transmission line assembly chip 1 of the present embodiment is mounted between the semiconductor chips 11 and 12 on the circuit board 13 to constitute a multi-chip module, the electrode pads 4 (i.e., metallic bumps) of the projecting portions will cover the electrode pads (15, 16) of the semiconductor chips (11, 12) so that highly accurate electric connection with the electrode pads of the semiconductor chips can be achieved.

In this case, it will be necessary that a pitch (p) of the electrode pads of the semiconductor chips is coincident with an array pitch of the metallic films 2 of the transmission line assembly chip 1, that is, substantially equal to an array pitch of the electrode pads 4, similarly to FIG. 2A.

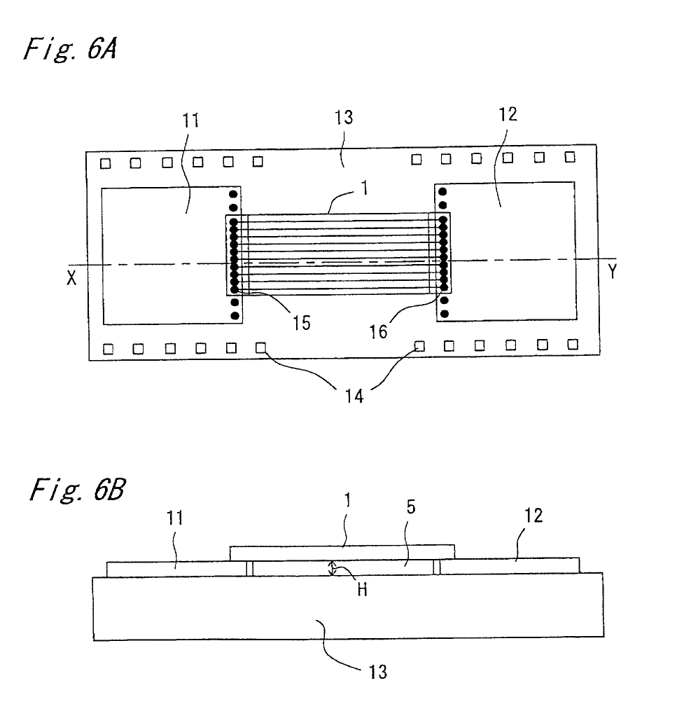

By further setting a height of the insulating supporting substrate 5 to be identical to a height of the semiconductor chips as to be described later with reference to FIG. 6B, stresses applied on the connection portions between the electrode pads may be minimized to thereby improve reliability of connection.

### EMBODIMENT 4

FIG. 5A illustrates a plan view of a transmission line assembly chip 1 according to the fourth embodiment of the present invention, and FIG. 5B shows a sectional view thereof when cut along cutting surface X-Y. The strap-like metallic films 2, strap-like dielectric films 3, supporting substrate 5, and projecting portions 4a are similar to those of the third embodiment, and the explanation thereof is omitted here.

The present embodiment differs from the third embodiment in that holes 6 for connection are formed in the projecting portions 4a of the metallic films 2, instead of forming electrode pads 4 for connection. When the transmission line assembly chip 1 of the present embodiment is disposed between the semiconductor chips (11, 12) to constitute a multi-chip module, a pitch of the holes of the assembly chip 1, that is, a pitch of the transmission lines should be made coincident with a pitch of the electrode pads (15, 16) of the semiconductor chips (11, 12). By this arrangement, it is possible to coincide a position of each of the holes 6 of the respective metallic films 2 and a position of each of the electrode pads of the semiconductor chips. By soldering or filling in a conductive paste into these holes 6 or by engaging the electrode pads of the semiconductor chips into the holes 6, the metallic films 2 serving as transmission lines and the electrode pads of the semiconductor chips can be surely electrically connected.

By further setting a height of the insulating supporting substrate 5 to be identical to a height of the semiconductor chips 11 and 12 as shown in FIG. 5B, lower surfaces 2a of the transmission line conductors 2 and the surfaces 11a and 12a of the semiconductor chips 11 and 12 may be made coincident with each other in horizontal plane. Thus, stresses applied on the connecting portions can be minimized between the holes and the electrode pads to thereby improve reliability of the connection.

### EMBODIMENT 5

FIG. 6A illustrates a plan view of a multi-chip module according to the fifth embodiment of the present invention formed by utilizing the transmission line assembly chip 1 of the present invention, and FIG. 6B shows a sectional view thereof when cut along cutting surface X-Y. Reference numerals 11, 12 denote semiconductor chips, reference numeral 13 denotes a circuit board, and reference numeral 14 denotes connecting pads 14 formed on the circuit board 13. In a similar manner to the embodiments shown in FIGS. 3-5, an insulation supporting substrate 5 may be adhered onto a rear surface of the assembly chip 1 using such as adhesives.

The multi-chip module of the present embodiment is comprised of the two semiconductor chips 11, 12 disposed on the circuit board 13 in combination with the transmission line assembly chip 1 according to the third embodiment. Signals requiring rapid transmission are transmitted through the transmission line assembly chip 1 between the two semiconductor chips. On the other hand, though signals lines or power lines that do not require rapid signal transmission are not illustrated in the drawings, the signal transmission and power supply are effected through wiring conductors formed on the circuit board 13 or formed in wiring layers within the circuit board.

As it is evident from FIG. 6A, since at least an array pitch of the metallic films 2 that are to be mutually connected and a pitch of the electrode pads 15, 16 of the semiconductor chips 11, 12 are made coincident, the electrode pads 4 of the assembly chip 1 and the electrode pads 15, 16 of the semiconductor chips 11, 12 may be connected at high accuracy.

In order to achieve electrical connection between the both electrode pads by using the transmission line assembly chip of the third embodiment, it is possible to employ a method of forming the electrode pads 4 on the lower surfaces of the metallic films 2 and then electrically connecting the electrode pads 4 to the electrode pads 15 (16) of the semiconductor chips through soldering or by using a conductive paste.

For electric connection between the electrode pads 4 and 15 (16) of the both chip members when using the transmission line assembly chip 1 of the fourth embodiment shown in FIG. 5A, it is possible to employ a method of filling a conductive paste or soldering paste into the holes (apertures) 6 for connection formed on the end portions of the metallic films 2 and then curing or melting the same.

In this construction, by setting a height H of the insulation supporting substrate 5 of the transmission line assembly chip 1 to be identical to a height of the semiconductor chips 11 and 12 as shown in FIG. 6B, the lower surfaces of the metallic films 2 and dielectric films 3 may be made coincident with a height of an upper surface of the semiconductor chips 11 and 12, and the metallic films 2 may contact the electrode pads 15, 16 of the semiconductor chips in a horizontal condition. It is consequently possible to reduce stresses applied on connecting terminal portions and thus to improve reliability.

Although the transmission lines 2 are formed as straight lines on the flat plane of the assembly chip 1 in FIG. 6A, it is also possible to dispose the assembly chip in a bent manner, depending on a positional relationship with respect to the semiconductor chips. Moreover, while two semiconductor chips are illustrated in FIG. 6A, it is possible to compose the multi-chip module by connecting a larger number (three or more) of semiconductor chips by using a plurality of transmission line chip assemblies 1 of the present invention.

### EMBODIMENT 6

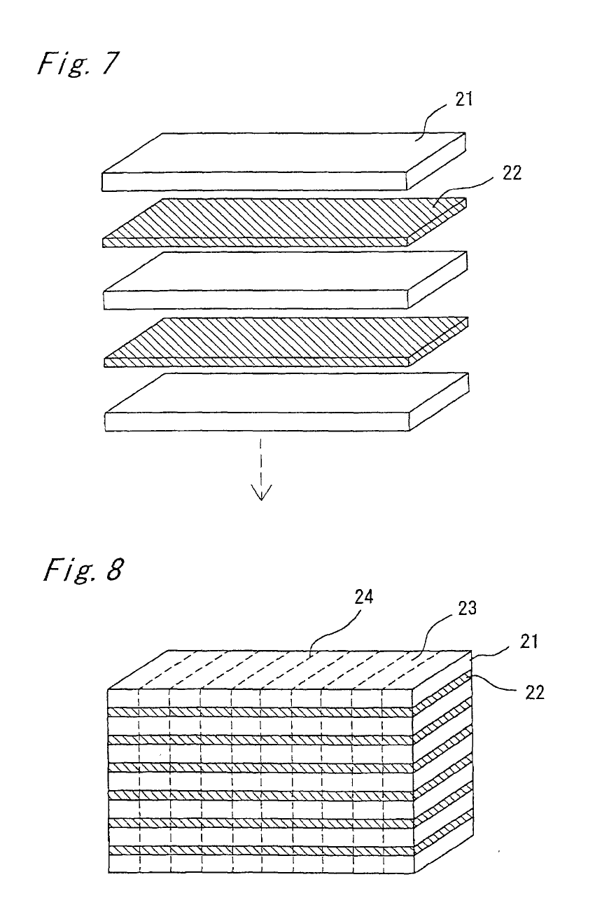

FIGS. 7 to 10 are process diagrams for explaining a method for manufacturing the transmission line assembly chip 1 of the present invention. The method for manufacturing the transmission line assembly chip 1 of the present embodiment will now be explained with reference to the drawings.

Reference 21 denotes film-like dielectric films of B-stage, and 22 denote film-like copper foils or films. As illustrated in FIG. 7, an uncured sandwich structure is formed by alternately laminating the dielectric films 21 of a specified thickness of e.g. 50 μm and copper films 22 of a specified thickness of e.g. 20 μm by a required number of layers. By heating and pressurizing the sandwich structure from upper and lower surfaces which are laminating surfaces, the electrode films 21 in prepreg conditions are cured. Simultaneously, adjoining copper films are adhered to constitute a cured sandwich structure 23 as illustrated in FIG. 8.

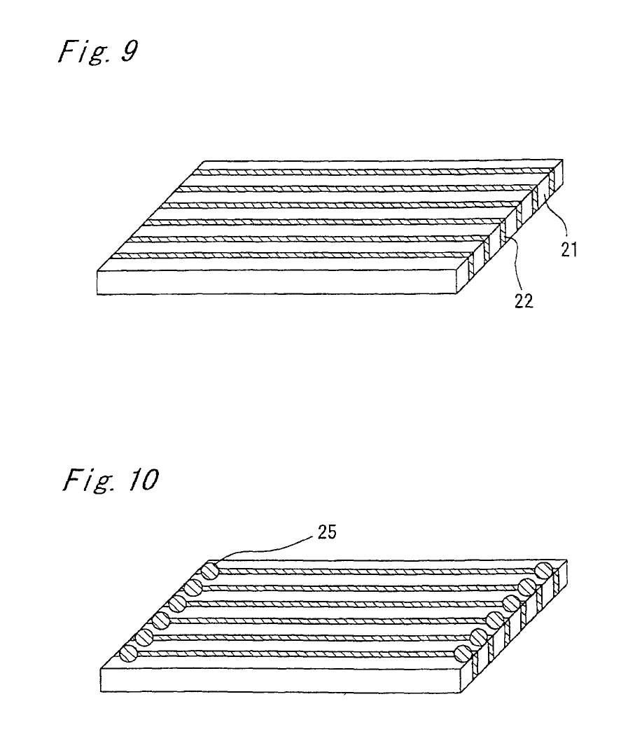

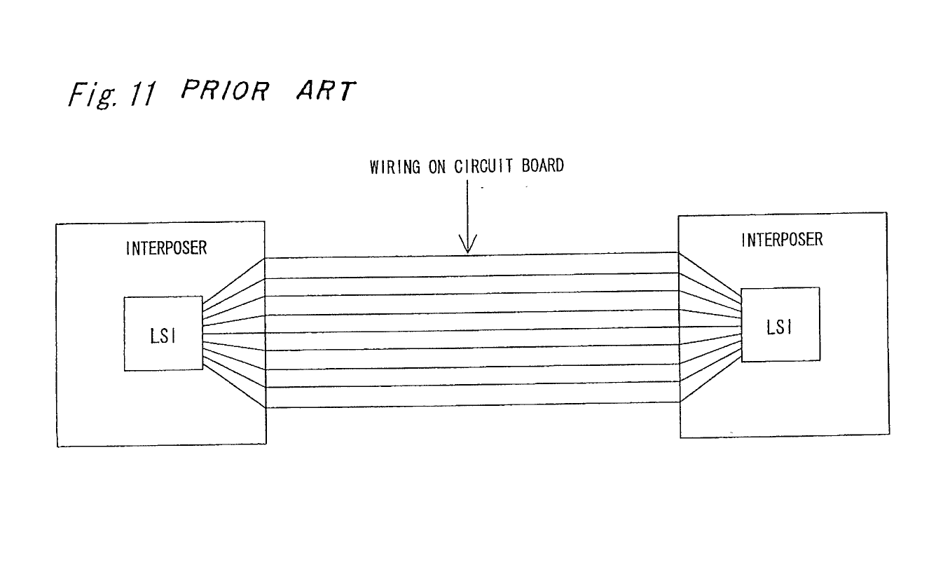

By cutting the sandwich structure along a laminating section as indicated by dotted lines 24 using a cutting blade or a wire saw into a specified thickness of e.g. 100 μm, there is obtained a structure as illustrated in FIG. 9 in which the copper films 22 are embedded in the dielectric films 21 at a specified pitch or interval. Characteristics impedance of the transmission lines of the present invention made of copper films 22 is determined through factors such as thickness of the copper films 22 and the dielectric films 21 after curing and shrinkage and dielectric constant of the dielectric films 21.

It is therefore necessary to control the thickness of the prepreg by estimating a shrinkage rate at the time of curing such that the thickness of the dielectric films 21 after curing satisfy a specified characteristic impedance. Finally, by forming pads or metallic bumps 25 on both ends of the copper films 22 that serve as transmission lines through metallic films for connection, the transmission line assembly chip 1 of the first embodiment as illustrated in FIG. 10 or FIG. 1 can be completed.

A resin impregnated sheet or resin impregnated fiber sheet comprised of one or more than two types of resin selected from glass epoxy composite, glass BT resin composite, epoxy resin and aramid epoxy resin may be employed as the dielectric film 21 of B-stage. For achieving high density, it is also possible to employ copper foils with resin such as epoxy resin for ease of handling when using particularly thin copper foils. In this case, the epoxy resin will also be count to the thickness of the dielectric film.

Moreover, in a similar manner as shown in FIG. 2B, the thickness in height of the assembly chip is made coincident to the thickness in height of the semiconductor chips. Thus, the level in height of the upper surface of the assembly chip is made coincident with the level in height of the upper surfaces of the semiconductor chips. Therefore, the surfaces of the transmission line assembly chip and semiconductor chips are made uniform to thereby facilitate the electrical connection between the electrode pads 4 and the I/O electrode pads 15 and 16.

By adhering an insulation supporting substrate 5 onto a rear surface of the transmission line assembly chip as illustrated in FIG. 10 using an adhesive, the transmission line assembly chip according to the second embodiment as illustrated in FIG. 3 may be completed.

Alternatively, an insulation supporting substrate 5 is adhered onto a surface on which the pads or metallic bumps are formed on both ends of the copper films 2 so as not to cover the pads or metallic bump portions on both sides. It is consequently possible to obtain the transmission line assembly chip of the third embodiment as illustrated in FIG. 4 arranged in that end portions of the copper films 2 and dielectric films 3 are project by specified lengths. In this case, the thickness of the supporting substrate is made to be identical to the thickness of the semiconductor chips, the connecting pads or bumps of the transmission line assembly chip 1 will be formed on a same plane so as to enable electric connection at high accuracy and free of torsions.

In the process of forming the assembly chip prior to forming the connecting pads or bumps, the holes for connection are formed by etching or laser irradiation in the neighborhoods of both ends of respective transmission lines made of copper foils as illustrated in FIG. 9, and thereafter the assembly chip is adhered onto a supporting substrate through an adhesive except for aperture portions (holes) on both ends, it is possible to obtain the transmission line assembly chip according to the fourth embodiment as illustrated in FIG. 5.

While methods for manufacturing a transmission line assembly chip have been explained in the above embodiment in which metallic foils and resin are employed, it is alternatively possible to employ a copper foil or nickel foil as the metallic foil and a green sheet of inorganic material such as low melting glass or low melting alumina etc. as the dielectric film.

After firing the laminated body of metallic foils and green sheets at a specified temperature and cutting the same in a sectional direction into a specified thickness, a transmission line assembly chip composed of inorganic materials may be completed. A transmission line assembly chip of inorganic materials may be used in high temperature environments owing to characteristics of the materials when compared to one made of resin.

As described above, transmission lines for rapid signal transmission between semiconductor chips are also regarded as a sort of chip member, and a transmission line assembly chip is disposed between the semiconductor chips to constitute a multi-chip module for signal transmission requiring especially rapid transmission.

The transmission line assembly chip has a structure in which strap-like metallic films and dielectric films are alternately arranged in the transverse direction in parallel, where an aspect ratio of the transmission lines is larger than 1, and a pitch between transmission lines is small, and the wiring density can be made high, and further exhibiting small wiring resistance considering width of the lines, and obtaining favorable matching properties of characteristic impedances of transmission lines. It is thus possible to achieve both, high density wiring as well as high-speed and low loss characteristics, and effects in view of industrial applicability are remarkable.

What is claimed is:

1. A transmission line assembly chip comprising an array of strap-like metallic films serving as transmission lines and dielectric films, wherein the metallic films and dielectric films are alternately arranged in parallel in a transverse direction thereof.

2. The transmission line assembly chip as claimed in claim 1, wherein each of the transmission lines composed of the strap-like metallic films has an aspect ratio larger than 1.

3. The transmission line assembly chip as claimed in claim 1, further comprising an insulation supporting substrate on which the transmission lines are disposed.

4. The transmission line assembly chip as claimed in claim 3, further comprising a conductive film formed on a rear surface of the insulation supporting substrate.

5. The transmission line assembly chip as claimed in claim 3, wherein end portions of the strap-like metallic films and the dielectric films are projected longer by a specified length than the insulation supporting substrate.

6. The transmission line assembly chip as claimed in claim 5, wherein terminal connection mechanisms are provided near the both end portions of the strap-like metallic films.

7. The transmission line assembly chip as claimed in claim 6, wherein the terminal connection mechanisms are electrode pads.

8. The transmission line assembly chip as claimed in claim 6, wherein the terminal connection mechanisms are connection holes buried by electric conductive material.

9. A multi-chip module comprising: semiconductor chips which are electrically connected through a transmission line assembly chip,
wherein the transmission line assembly chip has an array of strap-like metallic films serving as transmission lines and dielectric films, wherein the metallic films and dielectric films are alternately arranged in parallel in a transverse direction thereof.

10. The multi-chip module as claimed in claim 9, wherein each of the transmission lines composed of the strap-like metallic films has an aspect ratio larger than 1.

11. The multi-chip module as claimed in claim 9, wherein the transmission line assembly chip further comprises an insulation supporting substrate on which the transmission lines are disposed.

12. The multi-chip module as claimed in claim 9, wherein pitches of electrode pads of the semiconductor chips are coincident with pitches of the array of the metallic films of the transmission line assembly chip.

13. The multi-chip module as claimed in claim 11, wherein a height of the insulation supporting substrate is identical to a height of the semiconductor chips.

14. A method of manufacturing a transmission line assembly chip, comprising the steps of:
sequentially laminating metallic films and dielectric films to form a sandwich-like structure; and
cutting the sandwich-like structure along a laminating section to be of a specified thickness.

15. The method as claimed in claim 14, further comprising the step of adhering the sandwich-like structure cut by the specified thickness onto an insulation supporting substrate using an adhesive.
